(19) United States
(12) Patent Application Publication
(10) Pub. No.: US 2018/0084682 A1
(43) Pub. Date: Mar. 22, 2018

(54) SHIELDING STRUCTURE FOR AN ELECTRONIC CIRCUIT

(71) Applicant: Jones Tech (USA), Inc., Cupertino, CA (US)

(72) Inventor: Xiaoning Wu, Beijing (CN)

(21) Appl. No.: 15/271,213

(22) Filed: Sep. 20, 2016

(51) Int. Cl. H05K 9/00; H05K 7/20

(52) U.S. Cl. CPC H05K 9/0081; H05K 9/0064; H05K 7/2039; H05K 9/0007

(57) ABSTRACT

Shielding an electronic circuit can include: forming an absorbing material around a perimeter of the electronic circuit such that the absorbing material provides a shielding wall that isolates the electronic circuit from electromagnetic interference; forming a conductive top cover over the absorbing material and the electronic circuit such that the conductive top cover provides a reflection loss for electromagnetic interference; and forming a grounding pad for electrically grounding the conductive top cover.

### BACKGROUND

Electronic circuits, e.g., integrated circuit chips used in a smartphones or other systems with radio frequency (RF) components, can generate electromagnetic interference, or be subjected to electromagnetic interference. Electromagnetic interference can hinder the desired functions of an electronic circuit.

An electronic circuit can be shielded from electromagnetic interference by enclosing the electronic circuit in a grounded metal can that acts as a Faraday cage for reflecting electromagnetic energy.

### SUMMARY

In general, in one aspect, the invention relates to a shielding structure for an electronic circuit. The shielding structure can include: an absorbing material deployed around a perimeter of the electronic circuit such that the absorbing material provides a shielding wall that isolates the electronic circuit from electromagnetic interference; a conductive top cover deployed over the absorbing material and the electronic circuit such that the conductive top cover provides a reflection loss for electromagnetic interference; and a grounding pad for electrically grounding the conductive top cover.

In general, in another aspect, the invention relates to a method for shielding an electronic circuit. The method can include: forming an absorbing material around a perimeter of the electronic circuit such that the absorbing material provides a shielding wall that isolates the electronic circuit from electromagnetic interference; forming a conductive top cover over the absorbing material and the electronic circuit such that the conductive top cover provides a reflection loss for electromagnetic interference; and forming a grounding pad for electrically grounding the conductive top cover.

Other aspects of the invention will be apparent from the following description and the appended claims.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIGS. 1A-1B illustrate a shielding structure for an electronic circuit in one or more embodiments.

FIG. 2 is a side view of a shielding structure for an electronic circuit in one or more embodiments.

FIG. 3 illustrates a shielding structure for an integrated circuit chip in a smartphone in one or more embodiments.

FIG. 4 illustrates a shielding structure for a set of integrated circuit chips in a digital radio in one or more embodiments.

FIG. 5 illustrates a method for shielding an electronic circuit in one or more embodiments.

### DETAILED DESCRIPTION

Reference will now be made in detail to the various embodiments of the present disclosure, examples of which are illustrated in the accompanying drawings. Like elements in the various figures are denoted by like reference numerals for consistency. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, have not been described in detail so as not to unnecessarily obscure aspects of the present disclosure.

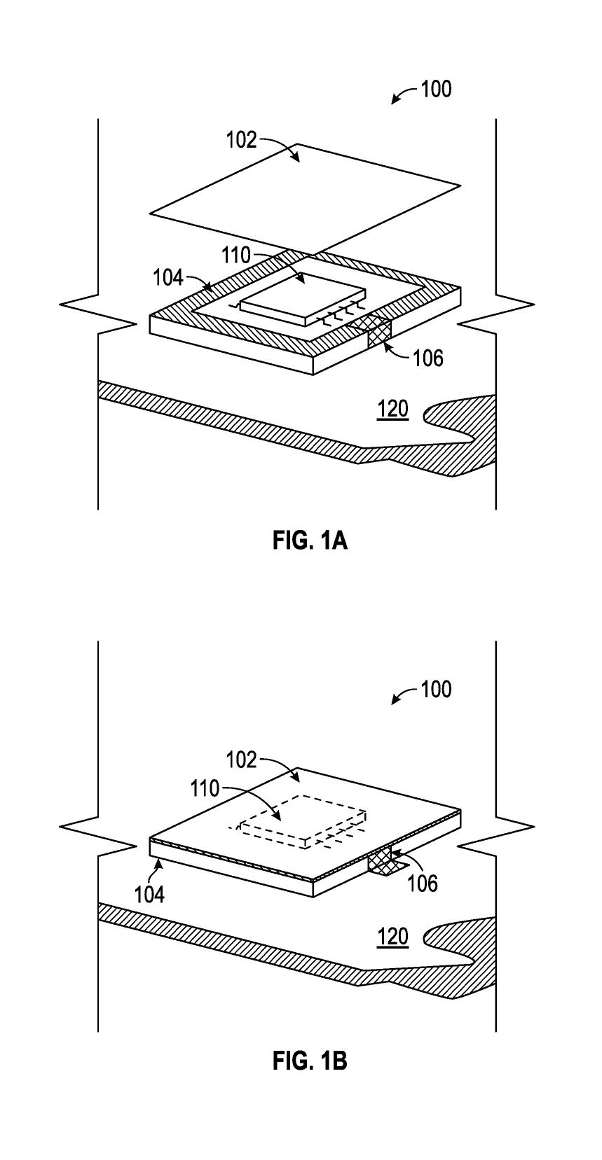

FIGS. 1A-1B illustrate a shielding structure 100 for an electronic circuit 110 in one or more embodiments. The shielding structure 100 provides a one-piece module that functions as an electromagnetic shield for the electronic circuit 110 by providing a combination of RF isolation and RF reflection. FIGS. 1A-1B provide an exploded-perspective view and perspective view, respectively, of the shielding structure 100.

The shielding structure 100 includes an absorbing material 104 deployed around a perimeter of the electronic circuit 110. The absorbing material 104 provides a shielding wall that isolates the electronic circuit 110 from electromagnetic interference.

The shielding structure 100 includes a conductive top cover 102 deployed over the absorbing material 104 and the electronic circuit 110. The conductive top cover 102 provides a reflection loss for electromagnetic interference.

The shielding structure 100 includes a grounding pad 106. The grounding pad 106 electrically grounds the conductive top cover 102 to a circuit board 120.

The absorbing material 104 can be any radio frequency (RF) absorbing material. The absorbing material 104 can be a pure RF absorbing material. The absorbing material 104 can be a rubber-based RF absorbing material. The absorbing material 104 can be a foam-based RF absorbing material. The absorbing material 104 can be a cured-in-place liquid material. The absorbing material 104 can be an adhesive material.

The conductive top cover 102 can be a conductive composite material. Examples of conductive composite materials for the conductive top cover 102 include conductive fabrics, electrically conductive structure materials, etc.

The conductive top cover 102 can be a metal foil. Examples of metal foils for the conductive top cover 102 include aluminum, copper, other metals, alloys of metals, etc.

In one or more embodiments, the conductive top cover 102 provides a heat sink. In one or more embodiments, the conductive top cover 102 includes a laminated heat spreading material, e.g., synthetic graphite.

The grounding pad 106 can be a conductive foam material. The grounding pad 106 can be a conductive rubber material, e.g., a conductive liquid form-in-place (FIP) rubber. The grounding pad 106 can be a conductive gasket. The grounding pad 106 can be compressed to provide enhanced grounding to the circuit board 120.

The absorbing material 104 can be bonded between the conductive top cover 102 and the circuit board 120.

The electronic circuit 110 can be an integrated circuit chip that is surface mounted on the circuit board 120, e.g., a printed circuit board. The electronic circuit 110 can include a set of integrated circuit chips that are mounted on the circuit board 120.

The absorbing material 104 can be deployed by die-cutting an absorbing material into a layout shape that surrounds the electronic circuit 110. The layout of the absorbing material 104 can provide a sidewall shielding of RF energy for the electronic circuit 110.

The absorbing material 104 can be coupled to the conductive top cover 102 and the circuit board 120, e.g., using a pressure-sensitive adhesive, without an electrically conductive connection to the circuit board 120 or the conductive top cover 102. The absorbing material 104 can be coupled to other components on the circuit board 120 using, e.g., a pressure-sensitive adhesive.

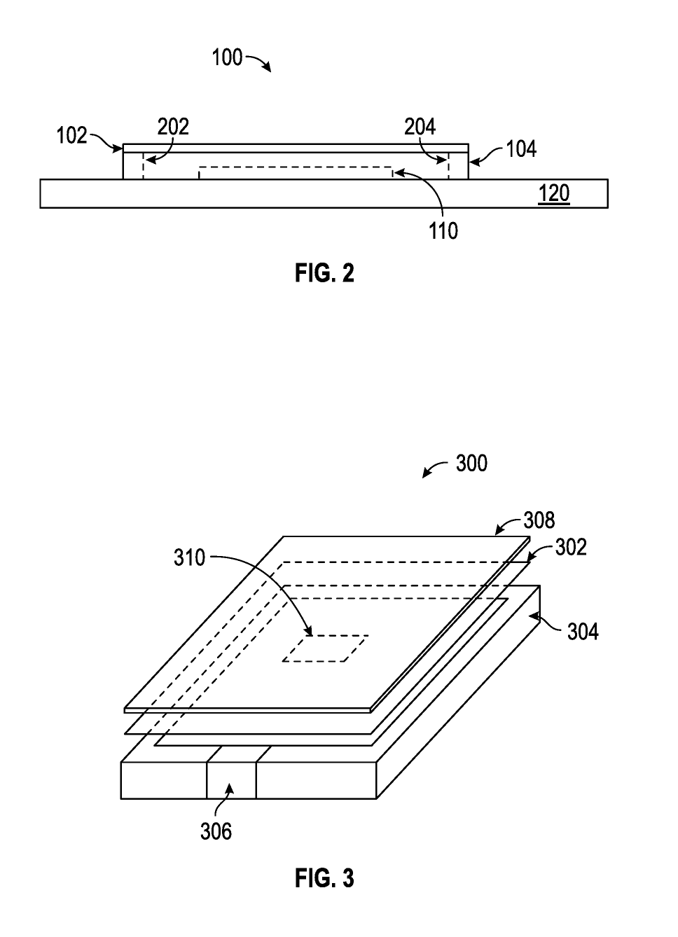

FIG. 2 is a side view of the shielding structure 100 for the electronic circuit 110 in one or more embodiments. A pair of opposing interior walls 202-204 of the absorbing material 104 deployed around the electronic circuit 110 is shown.

FIG. 3 is an exploded view of a shielding structure 300 for an integrated circuit chip 310 in a smartphone in one or more embodiments. The shielding structure 300 provides a one-piece module that functions as both an electromagnetic shield and a heat spreader.

The shielding structure 300 includes an absorbing material 304 formed around a perimeter of the integrated circuit chip 310, and further includes a conductive top cover 302 over the integrated circuit chip 310 and the absorbing material 304. The absorbing material 304 provides a shielding wall that isolates the integrated circuit chip 310 from electromagnetic interference. The conductive top cover 302 shields the integrated circuit chip 310 from electromagnetic interference by providing an RF reflection loss between the conductive top cover 302 and a printed circuit board upon which the integrated circuit chip 310 is mounted, while the absorbing material 304 isolates the integrated circuit chip 310 from RF signals.

The conductive top cover 302 is electrically grounded to the printed circuit board upon which the integrated circuit chip 310 is mounted. In one or more embodiments, the conductive top cover 302 is electrically grounded via a grounding pad 306.

The shielding structure 300 further includes a layer 308 of heat spreading material laminated on the conductive top cover 302. The layer 308 avoids hot spots by spreading heat generated by the integrated circuit chip 310. The layer 308 can be a synthetic graphite material.

The conductive top cover 302 can be a 10 micrometer layer of copper foil and the layer 308 can be a 25 micrometer sheet of graphite. The layer 308 can be laminated on the conductive top cover 302 and covered with a 5 micrometer polyethylene terephthalate (PET) covering film.

The conductive top cover 302 can be heat coupled to the integrated circuit chip 310 via a pressure sensitive adhesive to transfer heat generated by the integrated circuit chip 310 to the layer 308 of synthetic graphite. The grounding pad 306 can be a conductive foam pad, an FIP liquid paste, or a conductive rubber material. The absorbing material 304 can be die cut to the proper shape and attached to the conductive top cover 302 via pressure sensitive adhesive.

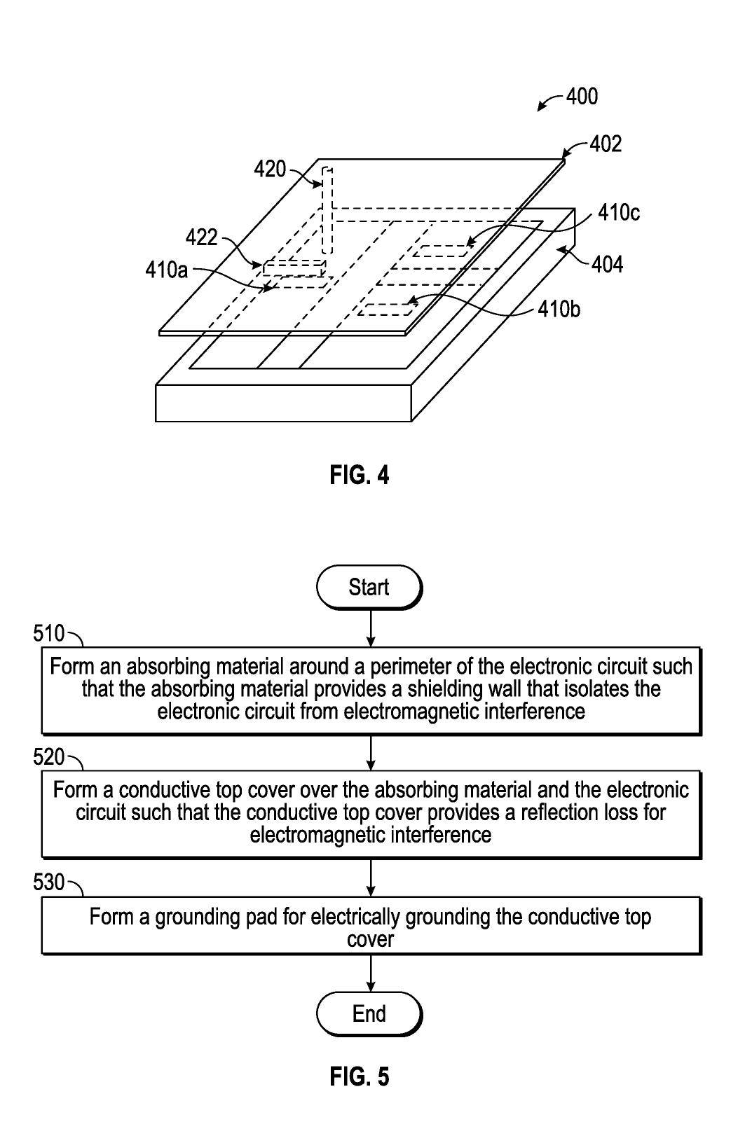

FIG. 4 is an exploded view of a shielding structure 400 for a set of integrated circuit chips 410a-c in a digital radio in one or more embodiments. The shielding structure 400 provides a one-piece module that functions as both an electromagnetic shield and a heat spreader for the integrated circuit chips 410a-c.

The shielding structure 400 includes an absorbing material 404 providing a shielding wall formed around the perimeters of the integrated circuit chips 410a-c, and further includes a conductive top cover 402 over the integrated circuit chips 410a-c and the absorbing material 404. The conductive top cover 402 shields the integrated circuit chips 410a-c from electromagnetic interference by providing a reflection loss between the conductive top cover 402 and a printed circuit board upon which the integrated circuit chips 410a-c are mounted, while the absorbing material 404 isolates the integrated circuit chips 410a-c from electromagnetic interference.

The conductive top cover 402 is electrically grounded to the printed circuit board upon which the integrated circuit chips 410a-c are mounted.

The conductive top cover 402 can be a sheet of aluminum that functions as both a shield for electromagnetic interference and as a heat sink.

The shielding structure 400 can include thermal pads, e.g., a thermal pad 422, for thermally coupling the integrated circuit chips 410a-c to the conductive top cover 402.

The absorbing material 404 can be die-cut to form an RF absorbing perimeter around each of the integrated circuit chips 410a-c. The conductive top cover 402 can be electrically grounded to the printed circuit board upon which the integrated circuit chips 410a-c are mounted using screws via one or more sleeves, e.g., a sleeve 420.

FIG. 5 illustrates a method for shielding an electronic circuit in one or more embodiments. While the various steps in this flowchart are presented and described sequentially, one of ordinary skill will appreciate that some or all of the steps can be executed in different orders and some or all of the steps can be executed in parallel. Further, in one or more embodiments, one or more of the steps described below can be omitted, repeated, and/or performed in a different order. Accordingly, the specific arrangement of steps shown in FIG. 5 should not be construed as limiting the scope of the invention.

At step 510, an absorbing material is formed around a perimeter of the electronic circuit such that the absorbing material provides a shielding wall that isolates the electronic circuit from electromagnetic interference. Forming an absorbing material around a perimeter of the electronic circuit can include die cutting an RF absorbing material. Forming an absorbing material around a perimeter of the electronic circuit can include deploying a foam-based RF absorbing material around the perimeter, deploying a cured-in-place liquid material around the perimeter, deploying an adhesive material around the perimeter, etc.

At step 520, a conductive top cover is formed over the absorbing material and the electronic circuit such that the conductive top cover provides a reflection loss for electromagnetic interference. Forming the conductive top cover can include forming a conductive composite material, forming a metal foil, etc. Forming the conductive top cover can include laminating a heat spreading material on the conductive top cover.

At step 530, a grounding pad is formed for electrically grounding the conductive top cover. Forming a grounding pad can include forming a conductive foam material, forming a conductive rubber material, forming a conductive gasket, etc.

While the foregoing disclosure sets forth various embodiments using specific diagrams, flowcharts, and examples, each diagram component, flowchart step, operation, and/or component described and/or illustrated herein may be implemented, individually and/or collectively, using a range of processes and components.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While the invention has been described with respect to a limited number of embodiments, those skilled in the art, having benefit of this disclosure, will appreciate that other embodiments may be devised which do not depart from the scope of the invention as disclosed herein.

1. A shielding structure for an electronic circuit, comprising:
a wall of an absorbing material formed on a circuit board holding the electronic circuit and surrounding a perimeter of the electronic circuit such that the wall isolates the electronic circuit from electromagnetic interference;
a conductive top cover coupled onto a top of the wall over the electronic circuit and enclosing the electronic circuit within the wall and the conductive top cover such that the conductive top cover provides a reflection loss for electromagnetic interference; and
a grounding pad for electrically grounding the conductive top cover.

2. The shielding structure of claim 1, wherein the absorbing material is an RF absorbing material.

3. The shielding structure of claim 1, wherein the absorbing material is a rubber-based RF absorbing material.

4. The shielding structure of claim 1, wherein the absorbing material is a foam-based RF absorbing material.

5. The shielding structure of claim 1, wherein the absorbing material is a cured-in-place liquid material.

6. The shielding structure of claim 1, wherein the absorbing material is an adhesive material.

7. The shielding structure of claim 1, wherein the conductive top cover is a conductive composite material.

8. The shielding structure of claim 1, wherein the conductive top cover is a metal foil.

9. The shielding structure of claim 1, wherein the conductive top cover provides a heat sink.

10. The shielding structure of claim 1, wherein the conductive top cover includes a laminated heat spreading material.

11. The shielding structure of claim 1, wherein the grounding pad comprises a conductive foam material.

12. The shielding structure of claim 1, wherein the grounding pad comprises a conductive rubber material.

13. The shielding structure of claim 1, wherein the grounding pad comprises a conductive gasket.

14. A method for providing a shielding structure for an electronic circuit, comprising:
forming a wall of an absorbing material on a circuit board holding the electronic circuit such that the wall surrounds a perimeter of the electronic circuit and isolates the electronic circuit from electromagnetic interference;
forming a conductive top cover onto a top of the wall over the electronic circuit and enclosing the electronic circuit within the wall and the conductive top cover such that the conductive top cover provides a reflection loss for electromagnetic interference; and
forming a grounding pad for electrically grounding the conductive top cover.

15. The method of claim 14, wherein forming a wall comprises die cutting an RF absorbing material.

16. The method of claim 14, wherein forming a wall deploying a foam-based RF absorbing material around the perimeter.

17. The method of claim 14, wherein forming a wall comprises deploying a cured-in-place liquid material around the perimeter.

18. The method of claim 14, wherein forming a wall comprises deploying an adhesive material around the perimeter.

19. The method of claim 14, wherein forming a conductive top cover comprises forming a conductive composite material.

20. The method of claim 14, wherein forming a conductive top cover comprises forming a metal foil.

21. The method of claim 14, further comprising laminating a heat spreading material on the conductive top cover.

22. The method of claim 14, wherein forming a grounding pad comprises forming a conductive foam material.

23. The method of claim 14, wherein forming a grounding pad comprises forming a conductive rubber material.

24. The method of claim 14, wherein forming a grounding pad comprises a forming a conductive gasket.
